(19) United States
(12) Patent Application Publication
(10) Pub. No.: US 2008/0002172 A1
(43) Pub. Date: Jan. 3, 2008

(54) MICROLITHOGRAPHIC PROJECTION EXPOSURE APPARATUS

(75) Inventor: Michael Totzeck, Schwaebisch Gmuend (DE)

Correspondence Address: FISH & RICHARDSON PC, P.O. BOX 1022, MINNEAPOLIS, MN, 55440-1022, US

(73) Assignee: CARL ZEISS SMT AG, Oberkochen (DE)

(21) Appl. No.: 11/855,526

(22) Filed: Sep. 14, 2007

Related U.S. Application Data
(62) Division of application No. 10/855,819, filed on May 27, 2004.

(30) Foreign Application Priority Data
May 30, 2003 (DE) 103 24 468.9

(51) Int. Cl. G03F 7/20

(52) U.S. Cl. 355/66; 355/71

(57) ABSTRACT

A microlithographic projection exposure apparatus comprises an illumination system for generating projection light, a projection lens for imaging a reticle onto a light-sensitive surface and an optical element arranged in the projection lens and adapted for setting a desired polarization of the projection light. The optical element has a support and at least one layer, which is arranged thereon, through which the projection light can pass and which has shape-birefringent grating patterns, the distance of which from one another is less than the wavelength of the projection light. The arrangement of the grating patterns varies locally within the at least one layer. The optical element makes it possible to compensate almost completely for undesired influences of birefringent optical components such as, for example, lenses made from CaF₂.

### BACKGROUND OF THE INVENTION

1. Field of the Invention

The invention generally relates to microlitho-graphic projection exposure apparatus having an illumination system for generating projection light and a projection lens for imaging a reticle onto a light-sensitive surface. The invention is particularly concerned with the compensation of birefringence in optical materials used in such a microlithographic projection exposure apparatus.

2. Description of Related Art

Microlithographic projection exposure apparatus, such as those used in the production of large-scale integrated electrical circuits for instance, have an illumination system which serves for generating a projection light bundle. The projection light bundle is directed at a reticle containing patterns to be imaged and being arranged in such a way as to be movable in an object plane of a projection lens. The latter images the patterns contained in the reticle onto a light-sensitive surface, which is situated in an image plane of the projection lens and can be deposited on a wafer, for example.

In such projection exposure apparatus, projection light in the deep ultraviolet (DUV) region is used increasingly, since the resolution of the projection lenses decreases, the smaller the wavelength of the projection light. At such short wavelengths, however, the absorption of conventional lens materials such as quartz or glass increases markedly. As a replacement for these materials, use is therefore being made more and more frequently of crystals made of fluorspar (CaF₂), which admittedly are technologically difficult to produce and process, but on the other hand are still highly transparent even at wavelengths of 157 nm and below.

Fluorspar crystals have the property of being (intrinsically) birefringent however. The term “birefringence” denotes the dependence of the refractive index and hence the propagation speed of light passing through on the polarization and direction of the light beam. The so-called intrinsic birefringence of CaF₂ is a result of the crystal structure and can be calculated relatively precisely if the crystal orientation and wavelength are known. More problems are presented by the birefringence induced by mechanical stresses in the crystal lattice. These stresses may be caused in the growth process of the crystal, but also by other influences such as lens mounts or the like. The stress-induced birefringence cannot generally be predicted and is therefore detectable only by metrological means.

The birefringence of CaF₂ lenses leads to an undesired increase of the resolution of the projection lens. Moreover, such lenses make it more difficult to set a desired polarization state of the projection light. It may be expedient, for example, to expose the light-sensitive surface on the wafer with circularly polarized light.

In order to compensate at least for the intrinsic birefringence of CaF₂ lenses, it is generally known to rotate a plurality of lenses composed of CaF₂ in a specific manner relative to one another. The greater the number of lenses composed of CaF₂, the easier it is to achieve compensation here. However, the birefringence can be only partially compensated for in this way, i.e. a non-negligible residual error always remains.

### SUMMARY OF THE INVENTION

The object of the invention is to improve a projection exposure apparatus in such a way that a desired polarization of the projection light can be set even more precisely than in known projection exposure apparatus.

A microlithographic projection exposure apparatus according to the invention comprises an illumination system for generating projection light, a projection lens for imaging a reticle onto a light-sensitive surface and an optical element arranged in the projection lens and adapted for setting a desired polarization of the projection light. The optical element has a support and at least one layer, which is arranged thereon, through which the projection light can pass and which has shape-birefringent grating patterns, the distance of which from one another is less than the wavelength of the projection light. The arrangement of the grating patterns varies locally within the at least one layer.

The invention is based on the finding that very precisely defined polarization properties can be set using shape-birefringent and locally varying grating patterns. The influence of the birefringence of CaF₂ lenses on the polarization of the projection light can thus be compensated for in a highly targeted manner. Shape birefringence is a property which stems from the inhomogeneous material distribution in gratings and emerges especially when the distance between the grating patterns is less than the wavelength of the incident light. Eventually, with sufficiently small grating patterns, only the zeroth diffraction order can still be propagated. The distance between the grating patterns in the optical element is therefore preferably less than 70%, in particular less than 30%, of the wavelength of the projection light.

The optical element is preferably arranged as near as possible to a pupil plane of the projection lens, in order that in another pupil plane the desired spatial distribution of the polarization is obtained.

Shape-birefringent grating patterns as such are known in the prior art. For example, an article by Z. Bomzon et al. entitled “Space-Variant Polarization-State Manipulated with Computer-Generated Subwave-length Gratings”, Optics & Photonics News, vol. 12, no. 12, December 2001, page 33, describes how the grating period and the direction of the grating lines can be determined by computer-aided calculation methods in such a way that light polarized by polarizers or retardation plates provided with such gratings can be converted into any desired polarization.

Hitherto, however, shape-birefringent patterns have never been considered for use in microlithographic projection exposure apparatus. This is due above all to the very short wavelengths used in such systems for the projection light. Although suitably small grating patterns in the subwavelength region can be produced by means of electron-beam lithography for example, these patterns then have such a low aspect ratio (ratio of pattern depth to pattern width) that only relatively low retardations owing to birefringence can be obtained in this way. For this reason, the above-mentioned article also only gives examples of gratings suitable for light with a wavelength of 10.6 μm, i.e. infrared light.

In order to be able to obtain even higher retardations using the shape-birefringent patterns, the projection light preferably passes through two—not necessarily different—shape-birefringent grating patterns. In this way, it is possible to obtain such a high retardation due to the birefringence that even the influence of birefringence on the projection light caused by relatively thick CaF₂ lenses can be compensated for thereby virtually completely. Owing to the fact that the arrangement of the grating patterns varies locally within the layer, it is also possible to compensate effectively for spatially very inhomogeneous perturbations of the polarization, such as that caused by stress-induced birefringence in CaF₂ lenses for instance.

The simplest possibility for getting the projection light to pass through at least two shape-birefringent grating patterns is to provide in the optical element at least two layers which are arranged one behind the other in the direction of propagation of the projection light and have shape-birefringent grating patterns. One support may be dispensed with in this case if two layers are arranged on opposite sides of a single support. It is however also possible to provide a plurality of, optionally interconnected, supports, on each of which one or more layers with shape-birefringent grating patterns are deposited. The grating patterns within the layers are preferably formed as line gratings, the period and/or orientation of which varies from layer to layer.

With a plurality of layers arranged one behind the other, it is possible to obtain a vertical structure resembling those which determine the polarization properties in crystals. If a plurality of layers are deposited directly on top of one another, however, it is not readily possible, for production-related reasons, to use a gas such as air as the medium surrounding the grating patterns. This is disadvantageous insofar as it means that only small differences in refractive index and hence high birefringences can be obtained. By contrast, if the layers are arranged on different supports, this restriction does not exist, which is why such elements can be used particularly advantageously when particularly high retardations owing to birefringence are to be obtained.

A further advantage of a plurality of layers is that this allows the polarization properties to be set with greater flexibility than is possible with only one layer. A single layer with birefringent grating patterns, in fact, has only the effect of a retardation plate, contrary to what is stated in the above-mentioned article by Z. Bomzon et al. With this, it is not possible for example to obtain a rotation of the polarization direction about an angle φ. Changing of the polarization as desired is only possible if the optical element has at least three layers with shape-birefringent grating patterns, two layers having at mutually corresponding points the effect of quarterwave plates rotated relative to one another and the layer arranged therebetween having the effect of a half-wave plate.

The support may be a dedicated substrate, e.g. a thin quartz plate. An additional substrate may however be dispensed with if a refractive optical element of the projection lens which is present in any case is used as the support. A layer of grating patterns can be produced for example by patterning a surface of the refractive optical element. As an alternative to this, it is possible to deposit a spatially suitably patterned dielectric, e.g. LaF₃, on the surface of the refractive optical element.

Another possibility for getting the projection light to pass through at least two shape-birefringent grating patterns is to provide a reflective optical element with a metal coating as the support, so that the projection light passes through the shape-birefringent grating patterns of the at least one layer once before and once after reflection on the metal coating. Such reflective optical elements with a metal coating which are suitable as supports are mostly found for example in a pupil plane in catadioptric parts of projection lenses.

The arrangement of the grating patterns which varies locally within the layer can be realized in different ways.

It is particularly simple in terms of production if the grating patterns within the at least one layer have a constant pattern depth, but a locally varying filling factor. The filling factor can be varied for example by changing the pattern width while keeping the grating period constant.

In an alternative embodiment for the variation of the arrangement of the grating patterns, the grating patterns within the at least one layer have a constant filling factor, but varying pattern depths. The filling factor is then preferably chosen such that a maximum birefringence results.

### BRIEF DESCRIPTION OF THE DRAWINGS

Various features and advantages of the present invention may be more readily understood with reference to the following detailed description taken in conjunction with the accompanying drawing in which:

FIG. 1 shows a meridional section through a projection exposure apparatus in a greatly simplified representation which is not to scale;

FIG. 2 shows a first exemplary embodiment of an optical element for setting a desired polarization in a perspective partial representation which is not to scale;

FIG. 3 shows a distribution of the pattern width over the area of the optical element illustrated in FIG. 2;

FIG. 4 shows a second exemplary embodiment of an optical element for setting a desired polarization in a perspective partial representation which is not to scale;

FIG. 5 shows a third exemplary embodiment of an optical element for setting a desired polarization in a sectional representation;

FIG. 6 shows a fourth exemplary embodiment of an optical element for setting a desired polarization in a sectional representation;

FIG. 7 shows a fifth exemplary embodiment of an optical element for setting a desired polarization in a perspective partial representation which is not to scale.

### DESCRIPTION OF PREFERRED EMBODIMENTS

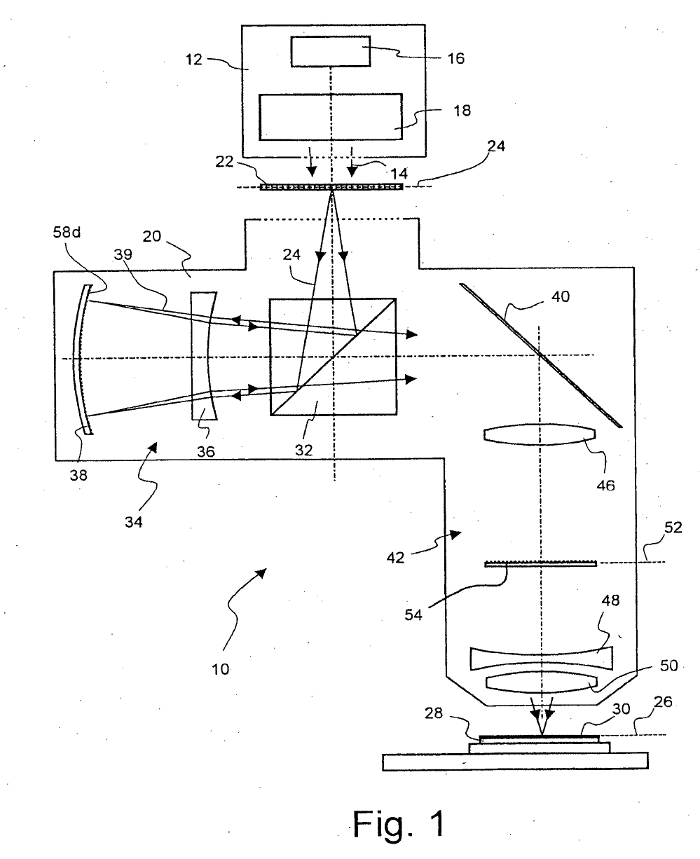

FIG. 1 show a meridional section through a projection exposure apparatus, denoted as a whole by 10, in a greatly simplified representation which is not to scale. The projection exposure apparatus 10 has an illumination system 12, which serves for generating a bundle of projection light 14 and comprises a light source 16 and illumination optics, indicated by 18. The wavelength λ of the projection light 14 lies in the deep ultraviolet region (DUV) and is assumed to be 193 nm. A reticle 22 is arranged between the illumination system 12 and a projection lens 20 of the projection exposure apparatus 10 in such a way as to be movable in an object plane 24 of the projection lens 20.

The projection lens 20 produces a minified image of patterns contained in the reticle 22 into its an image plane 26 of the projection lens 20. A light-sensitive surface 30, which may be a photoresist for example and is deposited on a wafer 28, is situated in the image plane 26.

The optical components contained in the projection lens 20 are merely indicated in FIG. 1 and comprise, inter alia, a beam splitter cube 32 and a catadioptric part 34, which includes a lens system indicated by 36 and an imaging mirror 38. For illustration, a beam path 39 of the projection light 14 is depicted in the catadioptric part 34 in FIG. 1. The projection lens 20 further contains a deviating mirror 40 and a dioptric part, denoted as a whole by 42, which contains a large number of lenses, although only a few of them are indicated by way of example in FIG. 1 and denoted by 46, 48 and 50.

The lens 50 lying nearest to the image plane 26 consists of a fluorspar crystal (CaF2) in a 111-cut. For simplicity, it is assumed that the lens 50 exhibits no stress-induced, but only intrinsic birefringence. The direction of the slower axis, along which the refractive index is greater, then varies over the pupil, this owing to the trigonal crystal symmetry, with a likewise trigonal symmetry. In addition, the magnitude of the retardation caused by the birefringence also varies over the pupil.

In order to compensate for the polarization effects caused by the lens 50, an optical element 54 which influences the polarization is arranged in a pupil plane 52 of the projection lens 20.

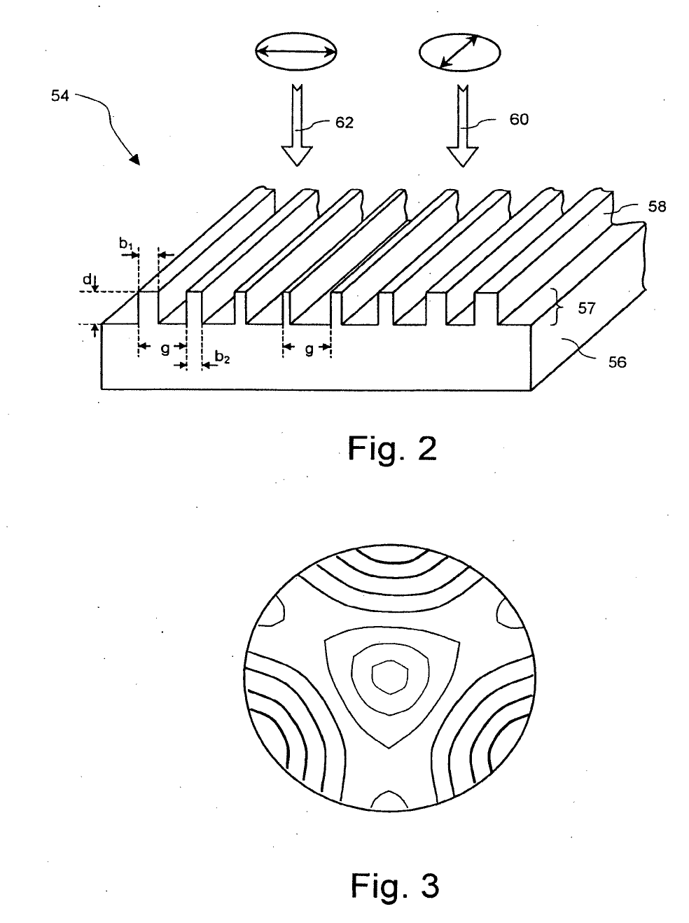

FIG. 2 shows the optical element 54 in a perspective partial representation which is not to scale. The optical element 54 comprises a support 56 made of quartz, on which a layer 57 composed of parallel grating patterns spaced apart from one another at a constant grating period g is arranged. In this exemplary embodiment, the grating patterns 58 have the same pattern depth d, but different pattern widths bᵢ. The grating period g of 40 nm is markedly less than the wavelength λ=193 nm of the projection light 14, so that the grating patterns 58 have a pronounced shape-birefringent effect and only the zeroth diffraction order is transmitted. The shape birefringence results in light 60 with a polarization parallel to the longitudinal extent of the grating patterns 58 being subjected to a greater effective refractive index than light 62 polarized perpendicularly thereto.

Since for the grating constant g<<λ holds true, the birefringence can be determined using the model of the effective medium. According to this model, for the refractive index nil for light 60 whose polarization is parallel to the grating patterns 58,
n_{∥}²=Fn²+(1−F)n₀², (1)
and for the refractive index n_{□} for light 62 whose polarization is perpendicular to the grating patterns 58,

$${n}_{• \dot{U}}^{2} = \frac{{n}^{2} {n}_{0}^{2}}{F {n}_{0}^{2} + ( 1 - F ) {n}^{2}} , \qquad ( 2 )$$

where n denotes the refractive index of the pattern material, n₀ the refractive index of the surrounding medium and F the filling factor. The filling factor F is obtained from the ratio of pattern width b to grating constant g, i.e.

$$F = \frac{b}{g} . \qquad ( 3 )$$

The birefringence Δn is defined as the difference between n_{∥} and n_{□}, i.e. Δn=n_{∥}−n_{□}.

In the case of the optical element 54, the pattern width b varies locally, so that the filling factor F and thus also the birefringence Δn is a function of the pupil coordinates Vₓ and V_{y}. For clarity, this dependence is suppressed in the notation hereinbelow, so that the relations given below apply only to one pupil point in each case.

In order to compensate for the birefringence of the lens 50, first of all its magnitude and direction have to be determined in dependence on the pupil coordinates. The intrinsic birefringence of Ca₂F can be calculated relatively easily; stress-induced birefringence distributions are preferably determined metrologically. This leads to a Jones matrix in the pupil, which is denoted as J hereinbelow. In order to obtain a desired overall polarisation with the aid of the optical element 54 using the Jones matrix J_{ideal}, the following matrix equation has to be solved:
K·J=J_{ideal}, (4)
where K is the Jones matrix of the optical element 54. In this case, the desired overall polarisation J_{ideal} may, for example, be constant over the pupil, so that J_{ideal} is the unit matrix. Depending on the application, it may however also be expedient to set other overall polarisations. For example, it is possible here to design the optical element 54 so as to produce the effect of a quarter-wave plate in combination with the lens 50.

At each point of the pupil, the effect of the birefringent lens 50 corresponds to that of a linear retardation plate rotated by an angle and having a given retardation. In order to compensate for this effect, the optical element 54 also has to act at each point of the pupil as a retardation plate rotated by an angle ψ and having the retardation Δφ. From the solution of equation (4), there is then obtained for each pupil coordinate a tuple (ψ, Δφ) which describes the direction ψ of the grating patterns 58 and the retardation Δφ caused thereby. From the retardation Δφ, it is then possible to determine via the relation

$$Δ n = \frac{λ}{2 π d} Δφ \qquad ( 5 )$$

the birefringence Δn and from this, with the aid of equations (1), (2) and (3) via the filling factor F, the pattern width b at the particular pupil coordinate.

The resultant distribution of the pattern widths b(Vₓ, V_{y}) over the pupil is illustrated qualitatively in FIG. 3. The pattern width here increases with increasing line thickness and lies between 2 nm and 16 nm in the exemplary embodiment illustrated. It can be clearly seen in FIG. 3 how the trigonal symmetry of the birefringence distribution in the CaF₂ crystal of the lens 50 is also reflected in a corresponding symmetry of the pattern-width distribution.

One possibility for producing the layer 57 with the grating patterns 58 is first of all to define the arrangement of the grating patterns 58 by electron-beam lithography and subsequently etch the grating grooves out of the quartz support 56. Even smaller grating patterns can also be produced by means of scanning tunnel or scanning force microscopy.

Instead of varying the pattern width b, it is of course equally possible to change the filling factor F and hence the birefringence Δn via the grating constant g. But since, besides the filling factor F, the pattern depth d also enters into equation (5), the filling factor F can also be kept constant and only the pattern depth d varied.

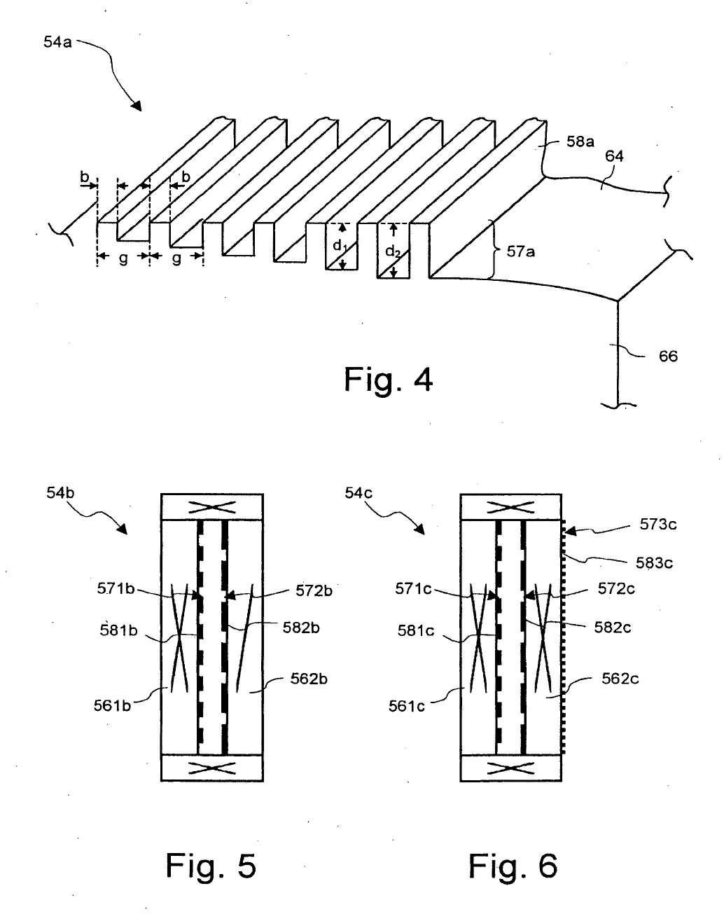

This case is shown in FIG. 4. The grating patterns 58a here have the same pattern width b and also the same grating constant g, but differ in respect of the pattern depth dᵢ. Furthermore, in the optical element 54a shown in FIG. 4, the layer 57a with the grating patterns 58a is arranged not on a dedicated support, but on a surface 64, near to the pupil, of a lens 66 present in any case in the projection objective 20 and made of quartz or CaF₂. The grating patterns 58a here can, as illustrated in FIG. 4, be patterned directly out of the surface 64 or else another material, such as LaF₃, deposited on the lens surface 64.

The retardations obtainable with the optical elements 54 and 54a owing to birefringence cannot, however, be increased to any level desired, since both the achievable birefringence and the technically producible aspect ratios are limited.

In order nevertheless to obtain higher retardations owing to birefringence, without having to increase the aspect ratio of the grating patterns, a plurality of the optical elements 54 and 54a illustrated in FIGS. 2 and 4 can be arranged one behind the other in such a way that the projection light passes through a plurality of shape-birefringent grating patterns.

One possibility for this is shown in FIG. 5. The optical element 54b shown in section therein comprises a first and second support 561b and 62b, respectively, on each of which is arranged a layer 571b and 572b, respectively, with shape-birefringent grating patterns 581b and 582b, respectively. The arrangements of the grating patterns 581b, 582b on the supports 561b, 562b differ from one another here, so that the two layers 571b, 572b have a different influence on the polarisation of the projection light 14 passing through. The layers 571b and 572b are deposited here on mutually facing areas of the supports 561b, 562b, so that they can both be arranged very precisely within a pupil plane of the projection objective 20. The space 68 between the layers 571b, 572b is filled with air or another gas, as a result of which a large difference in refractive index and hence a high birefringence can be obtained.

Besides the greater retardation achievable owing to the overall greater effective pattern depth, an arrangement with a plurality of layers also has the advantage that it provides an additional degree of design freedom. This makes it possible also to compensate for the effects of such birefringent elements which do not correspond to those of a retardation plate.

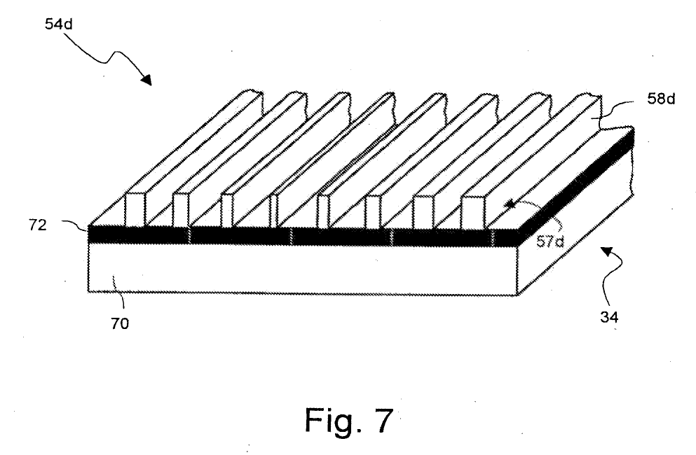

In the optical element 54c shown in a sectional representation in FIG. 6, a total of three layers 571c, 572c and 573c with shape-birefringent grating patterns 581c, 582c and 583c, respectively, are arranged one behind the other on two supports 561c, 562c, the arrangements of which differ from one another. The support 562c here carries on its front side and its rear side in each case one layer 572c and 573c, respectively. The grating patterns 581c, 582c and 583c here are chosen such that for each pupil coordinate the first layer 571c and the third layer 573c each have the effect of quarter-wave plates rotated relative to one another, while the layer 572c arranged therebetween has the effect of a half-wave plate. In this way, with the optical element 54c the polarisation of projection light 14 passing through can be changed as desired.

A further possibility for achieving passage through shape-birefringent grating patterns more than once in order to obtain higher retardations is shown in FIG. 7. The optical element 54d shown in a perspective and partial view therein is part of the mirror 38 which is arranged in the catadioptric part 34 of the projection objective 20 and comprises a mirror body 70 and a metal coating 72 deposited thereon and composed of a layer system.

The layer 57d, with diffraction patterns 58d corresponding to those of the optical element 54 shown in FIG. 2, is deposited here directly on the metal coating 72. Projection light 14 directed at the mirror 38l thus passes through the diffraction patterns 58d twice, namely a first time before it strikes the metal coating 72, and a second time after it has been reflected on the metal coating 72.

For simplicity, the curvature of the mirror 72 is not shown in FIG. 7 and can only be seen in FIG. 1.

It goes without saying that optical elements with a plurality of layers or layers passed through more than once can also be advantageously employed when particularly high retardation owing to shape birefringence is not important, but simple production of the layers is the main concern. For instance, in the exemplary embodiment shown in FIG. 7, the aspect ratio can be reduced by a factor of 2 compared with an arrangement with only one layer passed through but of otherwise identical design.

Optical elements with a plurality of layers can also be realised, as an alternative to the configurations described above, by arranging the layers with the birefringent grating patterns directly on top of one another, i.e. separated only by a surrounding dielectric. However, the advantage of a particularly high degree of compactness is then offset by the disadvantage that all solid dielectrics have a higher refractive index than air for instance, thereby reducing the birefringence and hence the obtainable retardation.

1. A microlithographic projection exposure apparatus, comprising:
a) an illumination system for generating projection light having a given wavelength,
b) a projection lens for imaging a reticle onto a light-sensitive surface, and
c) an optical element arranged in the projection lens and adapted for setting a desired polarization of the projection light, wherein said optical element includes
i) a support,
ii) at least one layer which is arranged on the support, through which the projection light can pass and which has shape-birefringent grating patterns, whose distance from one another is less than the wavelength of the projection light, and whose arrangement varies locally within the at least one layer.

2-10. (canceled)

11. The projection exposure apparatus according to claim 1, wherein the support is a reflective optical element with a metal coating, so that the projection light passes through the shape-birefringent grating patterns of the at least one layer once before and once after reflection on the metal coating.

12. The projection exposure apparatus according to claim 11, wherein the reflective optical element is arranged in a pupil plane of a catadioptric part of the projection lens.

13-18. (canceled)

19. An optical system, comprising:
a reflective optical element, said element comprising shape-birefringent grating patterns having a locally varying arrangement,
wherein the optical system is a microlithographic projection exposure apparatus.

20. The system of claim 19, wherein the system comprises an illumination system for generating projection light having a wavelength.

21. The system of claim 20, wherein adjacent grating pat-terns are spaced apart from another by a distance which is smaller than 70% of the wavelength of the projection light.

22. The system of claim 21, wherein the distance is smaller than 30% of the wavelength of the projection light.

23. The system of claim 19, wherein the grating patterns are formed as line gratings having a varying period.

24. The system of claim 19, wherein the grating patterns are formed as line gratings having a varying orientation.

25. The system of claim 19, wherein the grating patterns have a constant pattern depth, but a locally varying filling factor.

26. The system of claim 19, wherein the grating patterns have a constant filling factor, but locally varying pattern depths.

27. The system of claim 19, wherein the reflective optical element comprises a support and a metal coating.

28. The system of claim 27, wherein the grating patterns are arranged on the metal coating.

29. The system of claim 19, wherein the reflective optical element is arranged in a catadioptric part of a projection lens included in the apparatus.
